(19) United States
(12) Patent Application Publication
(10) Pub. No.: US 2008/0203482 A1
(43) Pub. Date: Aug. 28, 2008

(54) Transistors having gate pattern for self-alignment with channel impurity diffusion region in active region and methods of forming the same

(75) Inventors: Sung-Hee Han, Seoul (KR); Seung-Hyun Park, Seoul (KR); Tae-Young Chung, Yongin-si (KR)

Correspondence Address: MILLS & ONELLO LLP, ELEVEN BEACON STREET, SUITE 605, BOSTON, MA, 02108, US

(73) Assignee: Samsung Electronics Co. Ltd., Suwon-si (KR)

(21) Appl. No.: 12/072,188

(22) Filed: Feb. 25, 2008

(30) Foreign Application Priority Data
Feb. 26, 2007 (KR) 10-2007-0019085

(51) Int. Cl. H01L 29/423

(52) U.S. Cl. 257/365; 257/E29.136

(57) ABSTRACT

A transistor having a gate pattern suitable for self-alignment with a channel impurity diffusion region in an active region includes an active region and an isolation layer disposed in a semiconductor substrate. The isolation layer is formed to define the active region. An insulating layer covering the active region and the isolation layer is disposed. The insulating layer has a channel-induced hole on the active region. A channel impurity diffusion region and a gate trench are formed in the active region to be aligned with the channel-induced hole. The insulating layer is removed from the semiconductor substrate. A gate pattern is disposed in the gate trench to overlap the channel impurity diffusion region.

### CROSS-REFERENCE TO RELATED APPLICATION

This application claims priority to Korean Application Serial No. 10-2007-0019085, filed in the Korean Intellectual Property Office on Feb. 26, 2007, the entire contents of which are hereby incorporated herein by reference.

### BACKGROUND OF THE INVENTION

1. Field of the Invention

The present invention relates to transistors of a semiconductor discrete device and manufacturing methods thereof, and more particularly, to transistors having a gate pattern suitable for self-alignment with a channel impurity diffusion region in an active region, and methods of forming the transistors.

2. Description of the Related Art

Typically, a semiconductor device is manufactured using a transistor that has the capability to drive current in the device. the transistor may have a gate pattern extending downward from an upper surface of an active region with a shrinking design rule of a semiconductor device. Also, the gate pattern is formed to be in contact with a channel impurity diffusion region in the active region. As a result, the transistor enables electrical characteristics of the semiconductor device to be made the same regardless of the application of the shrinking design rule to the semiconductor device using the gate pattern and the channel impurity diffusion region.

However, the gate pattern of the transistor may not be aligned well with the channel impurity diffusion region in the active region. This is because the gate pattern is formed by filling a gate trench that extends downward from the upper surface of the active region to expose the channel impurity diffusion region. At this time, the gate trench and the channel impurity diffusion region are formed in the active region using semiconductor photo processes that are performed twice. The semiconductor photo processes are performed in the active region so that the gate trench and the channel impurity diffusion region are aligned with each other with a process margin. Therefore, in the case in which a process environment is not stable, the semiconductor photo processes may degrade the alignment relationship between the gate pattern and the channel impurity diffusion region.

Another alignment relationship between a gate (corresponding to the gate pattern) and a high-concentration impurity layer (corresponding to the channel impurity diffusion region) is disclosed in Japanese Patent Publication No. 9-97907 to Jeon Chang Gi. According to Japanese Patent Publication No. 9-97907, the high-concentration impurity layer is formed in a semiconductor substrate. The high-concentration impurity layer is disposed only in a predetermined region of the semiconductor substrate using a semiconductor photo process. A trench is formed in the semiconductor substrate to expose the high-concentration impurity layer. The trench may be formed using other semiconductor photo processes. A gate filling the trench is formed. The gate is formed to overlap the high-concentration impurity layer.

However, the high-concentration impurity layer and the trench are sequentially formed in an active region using semiconductor photo processes that are performed twice. The active region has the trench and the high-concentration impurity layer aligned with each other with different process margins with respect to the region. When a process environment is unstable, the high-concentration impurity layer and the trench may not be aligned well with each other. As a result, the gate may degrade electrical characteristics of the semiconductor device.

### SUMMARY OF THE INVENTION

An embodiment of the invention provides transistors having a gate pattern suitable for self-alignment with a channel impurity diffusion region in an active region.

Another embodiment of the invention provides methods of forming a transistor having a gate pattern that may be self-aligned with a channel impurity diffusion region in an active region using an insulating layer defining a channel-induced hole on the active region.

According to one aspect, the present invention is directed to a transistor having an isolation layer formed in a semiconductor substrate to define an active region. A first gate pattern protrudes from an upper surface of the active region and extends downward from the upper surface of the active region. The first gate pattern extends from the active region in parallel with the upper surface of the active region to thereby be in contact with an upper surface of the isolation layer. A channel impurity diffusion region is disposed below the upper surface of the active region and surrounds the gate pattern. The channel impurity diffusion region has different volumes at both sides of the gate pattern.

In one embodiment, a second gate pattern spaced apart from the first gate pattern by a predetermined distance is disposed in the active region and is surrounded by the channel impurity diffusion region. The second gate pattern protrudes from the upper surface of the active region, extends downward from the upper surface of the active region, and extends from the active region in parallel with the upper surface of the active region to thereby be in contact with the upper surface of the isolation layer.

In one embodiment, the first and second gate patterns are respectively disposed at both edges of the channel impurity diffusion region along the active region to sequentially pass through the patterns.

The channel impurity diffusion region can have different volumes at both sides of the second gate pattern.

The channel impurity diffusion region can be formed to be smaller than the upper surface of the active region and to face the upper surface of the active region.

In one embodiment, a gate insulating layer is disposed on the active region to pass through between the first gate pattern, the second gate pattern, and the active region. The gate insulating layer is in contact with the channel impurity diffusion region below the first and second gate patterns.

In one embodiment, each of the first and second gate patterns has a gate and a gate capping pattern that are sequentially stacked, and the gate insulating layer electrically insulates the first gate pattern, the second gate pattern, and the active region from one another, and partially surrounds the gate.

In one embodiment, the gate insulating layer is formed of silicon oxide or metal oxide.

In one embodiment, the gate insulating layer is formed of a material in which a metal or non-metal atom is inserted into a silicon oxide lattice.

According to another aspect, the present invention is directed to a method of forming a transistor. The method includes forming an active region and an isolation layer in a semiconductor substrate. The isolation layer is formed to isolate the active region. A lower pad layer, an intermediate pad layer, and an upper pad layer covering the active region and the isolation layer are sequentially formed. The upper pad layer, the intermediate pad layer, and the lower pad layer have a channel-induced hole. The channel-induced hole is formed to expose the lower pad layer. A channel spacer pattern is formed in contact with a sidewall of the channel-induced hole to expose the intermediate pad layer. A channel plug pattern is formed filling the channel-induced hole. A gate trench is formed in the active region by sequentially etching the channel spacer pattern and the lower pad layer using the intermediate pad layer and the channel plug pattern as an etch mask. The intermediate pad layer, the channel plug pattern, and the lower pad layer are removed from the semiconductor substrate. A first gate pattern which fills the gate trench and is in contact with an upper surface of the isolation layer is formed.

In one embodiment, forming the first gate pattern comprises: sequentially forming a gate layer and a gate capping layer on the active region and the isolation layer to fill the gate trench; forming a photoresist pattern on the gate capping layer to overlap the gate trench; sequentially etching the gate capping layer and the gate layer using the photoresist pattern as an etch mask; and removing the photoresist pattern from the semiconductor substrate. The first gate pattern protrudes from an upper surface of the active region, extends downward from the upper surface of the active region, and extends toward the isolation layer from the active region in parallel with the upper surface of the active region.

In one embodiment, forming the gate trench comprises: removing the channel spacer pattern using the intermediate pad payer and the channel plug pattern as an etch mask, and the lower pad layer as an etch buffer layer; and removing the lower pad layer, and then partially etching the active region using the intermediate pad layer and the channel plug pattern as an etch mask. The lower pad layer is formed of an insulating material having the same etch rate as the intermediate pad layer, and the upper pad layer is formed of an insulating material having a different etch rate from the intermediate pad layer.

In one embodiment, forming the channel spacer pattern and the channel plug pattern comprises; forming a channel spacer layer on the upper pad layer to conformally cover the channel-induced hole; forming a channel impurity diffusion region in the active region through the channel-induced hole using the channel spacer layer as a mask; forming a channel spacer surrounding a sidewall of the channel-induced hole by etching the entire surface of the channel spacer layer to expose the upper pad layer and the lower pad layer; forming a channel plug in contact with the channel spacer and the lower pad layer, and filling the channel-induced hole; and etching the channel plug, the channel spacer, and the upper pad layer. The channel spacer layer is formed of an insulating material having the same etch rate as the upper pad layer, and the channel plug is formed of an insulating material having the same etch rate as the intermediate pad layer.

Forming the upper pad layer, the intermediate pad layer, and the lower pad layer to have the channel-induced hole comprises: forming a photoresist layer on the upper pad layer to overlap the first gate pattern in the active region and have an opening exposing the upper pad layer; sequentially etching the upper pad layer and the intermediate pad layer, and then partially etching the lower pad layer using the photoresist layer as an etch mask; and removing the photoresist layer from the semiconductor substrate.

In one embodiment, the method further comprises forming a second gate pattern in the active region to be spaced apart from the first gate pattern by a predetermined distance. the second gate pattern protrudes from the upper surface of the active region, extends downward from the upper surface of the active region, and extends toward the isolation layer from the active region in parallel with the upper surface of the active region.

In one embodiment, the first and second gate patterns are respectively formed at both edges of the channel impurity diffusion region along the active region to sequentially pass through the patterns.

In one embodiment, the channel impurity diffusion region is formed to have different volumes at both sides of either the first gate pattern or the second gate pattern.

In one embodiment, the channel impurity diffusion region is formed to be smaller than the upper surface of the active region and to face the upper surface of the active region.

In one embodiment, the method further includes forming a gate insulating layer on the active region to pass through the first gate pattern, the second gate pattern, and the active region. The gate insulating layer is formed to be in contact with the channel impurity diffusion region below the first and second gate patterns.

In one embodiment, each of the first and second gate patterns is formed to have a gate and a gate capping pattern that are sequentially stacked, and the gate insulating layer electrically insulates the first gate pattern, the second gate pattern, and the active region from one another and partially surrounds the gate.

In one embodiment, the gate insulating layer is formed of silicon oxide or metal oxide.

In one embodiment, the gate insulating layer is formed of a material in which a metal or non-metal atom is inserted into a silicon oxide lattice.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 illustrates a layout view of transistors according to an exemplary embodiment of the present invention.

FIG. 2 contains cross-sectional views taken along lines I-I′ and II-II′ of FIG. 1.

FIGS. 3 to 8 are cross-sectional views taken along lines I-I′ and II-II′ of FIG. 1, illustrating a method of forming the transistors according to an exemplary embodiment of the present invention.

### DETAILED DESCRIPTION OF THE INVENTION

The present invention will now be described more fully hereinafter with reference to the accompanying drawings, in which preferred embodiments of the invention are shown. In the drawings, the thickness of layers and regions are exaggerated for clarity. In addition, when a layer is described to be formed on another layer or on a substrate, means that the layer may be formed on the other layer or on the substrate, or a third layer may be interposed between the layer and the other layer or the substrate.

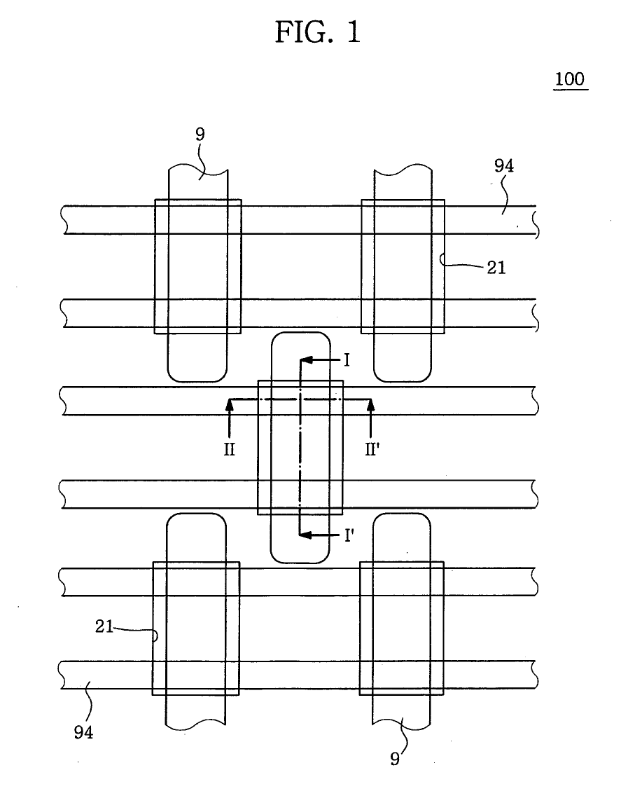

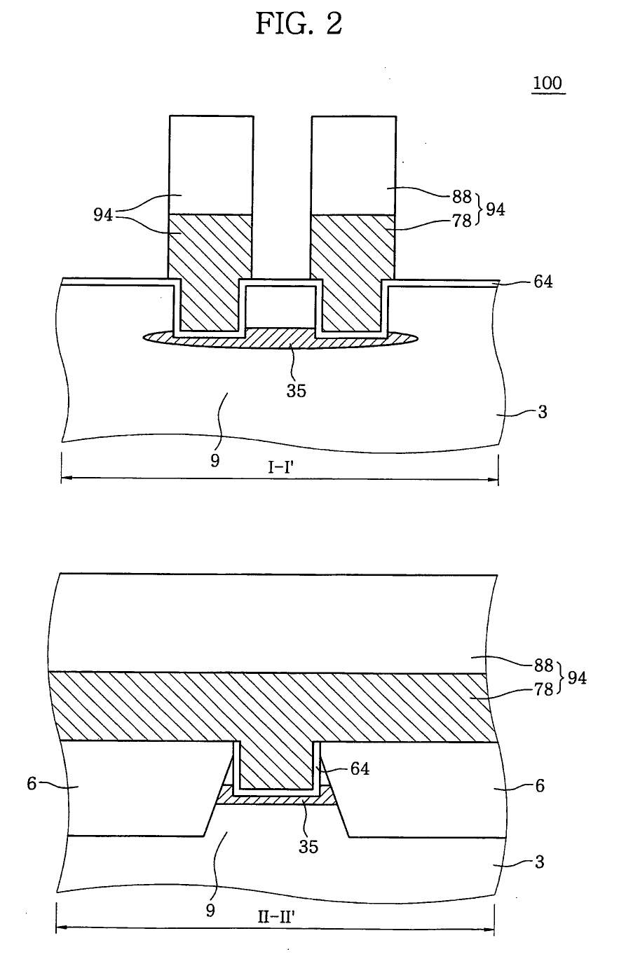

FIG. 1 illustrates a layout view of transistors having a gate pattern suitable for self-alignment with a channel impurity diffusion region in an active region, according to an exemplary embodiment of the present invention, and FIG. 2 contains cross-sectional views taken along lines I-I′ and II-II′ of FIG. 1.

Referring to FIGS. 1 and 2, a transistor 100 according to the present invention includes two gate patterns 94. Each of the gate patterns 94 has a gate 78 and a gate capping pattern 88 that are sequentially stacked. The gate capping pattern 88 may be formed of silicon nitride. The gate capping pattern 88 may be formed of an insulating material, in which a metal atom and/or a non-metal atom is in a silicon oxide lattice. The gate 78 may be formed of a silicon-based conductive material. An active region 9 surrounding the gate patterns 94 is disposed in a semiconductor substrate 3 as illustrated in FIG. 2. The semiconductor substrate 3 has conductivity.

More specifically, the semiconductor substrate 3 has an isolation layer 6 and the active region 9 as illustrated in FIG. 2. The isolation layer 6 defines the active region 9. The gate patterns 94 protrude from an upper surface of the active region 9, and extend downward from the upper surface of the active region 9 as illustrated in FIG. 2. As a result, the active region 9 may be formed to partially surround each gate 78 of the gate patterns 94 as illustrated in FIG. 2. Also, the gate patterns 94 extend from the active region 9 in parallel with the upper surface of the active region 9 as illustrated in FIG. 1 or 2, so that they may be in contact with an upper surface of the isolation layer 6 as illustrated in FIG. 2.

Referring again to FIGS. 1 and 2, a channel impurity diffusion region 35 is disposed in the active region 9 to overlap the gate patterns 94 as illustrated in FIG. 2. The channel impurity diffusion region 35 may be disposed below the upper surface of the active region 9 to surround the gate patterns 94. The channel impurity diffusion region 35 may have different volumes at both sides of a selected gate pattern 94. The gate patterns 94 may be respectively disposed at edges of the channel impurity diffusion region 35 along the active region 9 to sequentially pass through the patterns 94. The channel impurity diffusion region 35 may have a conductivity type that is either the same as or different from the semiconductor substrate 3.

The channel impurity diffusion region 35 may be smaller than the upper surface of the active region 9, and may face the upper surface of the active region 9. A gate insulating layer 64 may be disposed on the active region 9. The gate insulating layer 64 may be formed on the active region 9 to pass through the gate patterns 94 and the active region 9. The gate insulating layer 64 may be in contact with the channel impurity diffusion region 35 below the gate patterns 94. As a result, each gate 78 of the gate patterns 94 may be in contact with the gate insulating layer 64 in the active region 9, and be in direct contact with the isolation layer 6 on the isolation layer 6.

The gate insulating layer 64 may be formed of silicon oxide or metal oxide. The gate insulating layer 64 may be formed of a material in which a metal or non-metal atom is inserted into a silicon oxide lattice. A plurality of active regions 9 may be formed to correspond to columns and rows of the semiconductor substrate 3, and disposed as illustrated in FIG. 1. Two or more gate patterns 94 may be disposed in the plurality of active regions 9 and the isolation layer 6 as illustrated in FIG. 1.

Methods of forming transistors having a gate pattern suitable for self-alignment with a channel impurity diffusion region in an active region will be described below with reference to the accompanying drawings.

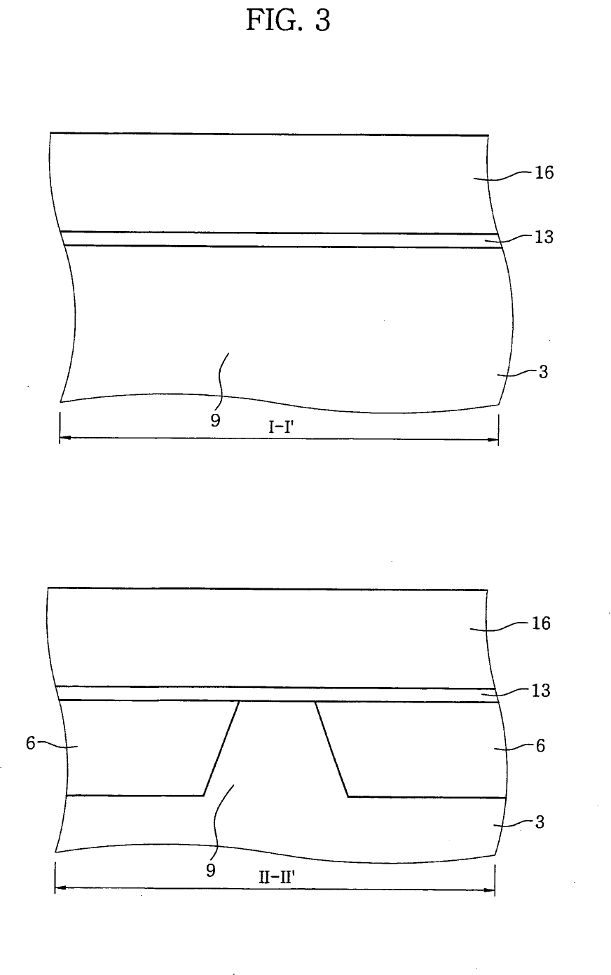

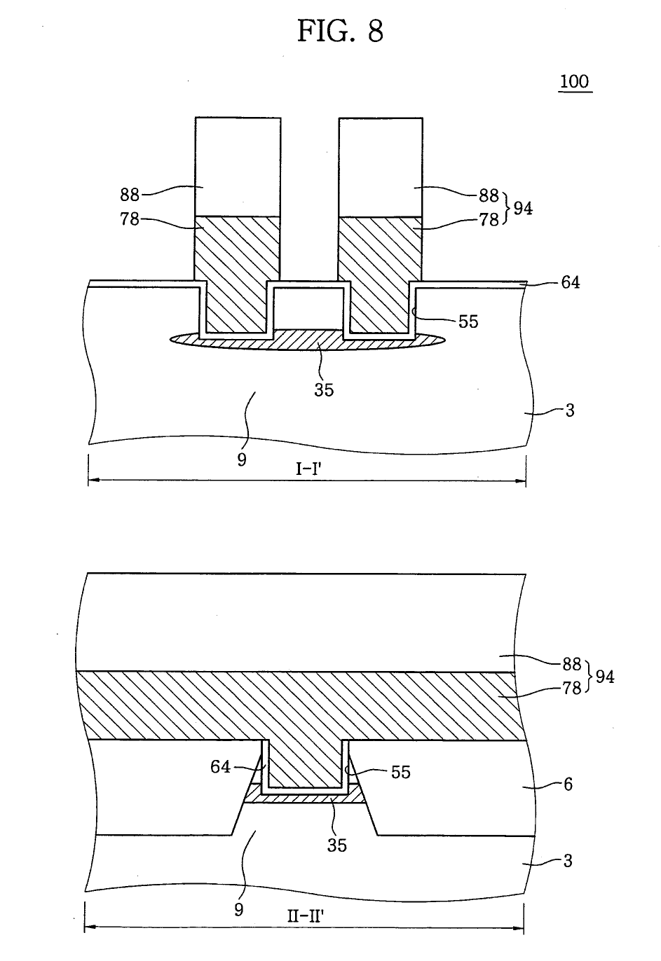

FIGS. 3 and 8 are cross-sectional views taken along lines I-I′ and II-II′ of FIG. 1, illustrating methods of forming transistors according to an exemplary embodiment of the present invention.

Referring to FIGS. 1 and 3, an isolation layer 6 is formed in a semiconductor substrate 3 as illustrated in FIG. 3. The isolation layer 6 may be formed to isolate an active region 9. The isolation layer 6 may be formed of at least one insulating layer. The semiconductor substrate 3 has a conductivity type. A lower pad layer 13 and an intermediate pad layer 16 covering the isolation layer 6 and the active region 9 are sequentially formed as illustrated in FIG. 3. The lower pad layer 13 may be formed of an insulating material having the same etch rate as the intermediate pad layer 16. The lower pad layer 13 and the intermediate pad layer 16 may be formed of silicon oxide. In addition, the lower pad layer 13 and the intermediate pad layer 16 may be formed of an insulating material in which a metal or non-metal atom is inserted into a silicon oxide lattice.

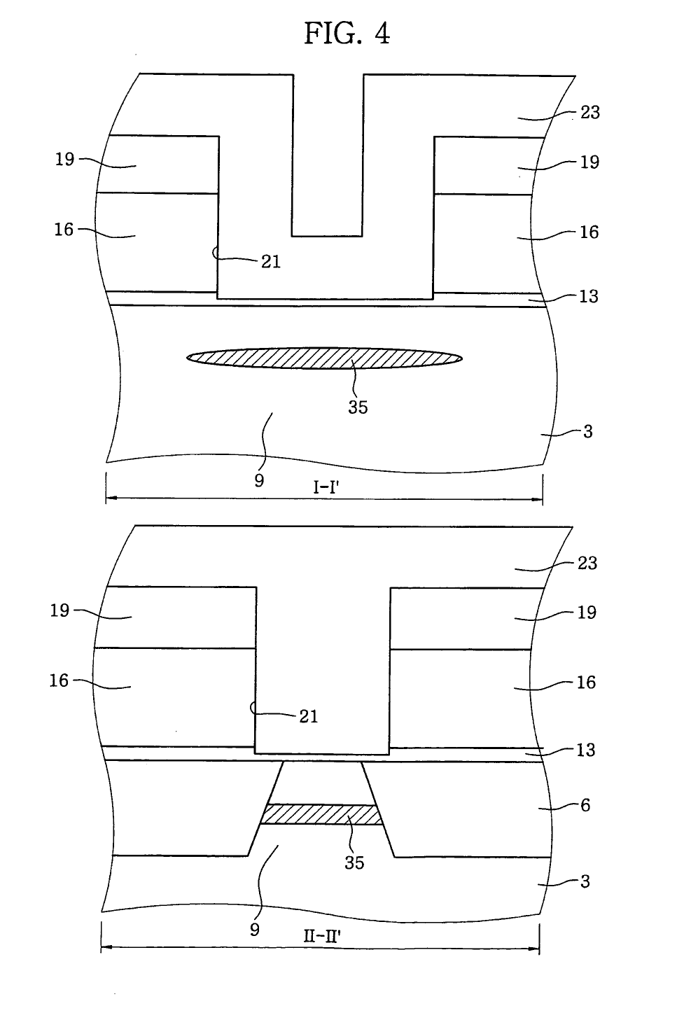

Referring to FIGS. 1 and 4, an upper pad layer 19 is formed on the intermediate pad layer 16 as illustrated in FIG. 4. The upper pad layer 19 may be formed of an insulating material having a different etch rate from the intermediate pad layer 16. The upper pad layer 19 may be formed of a material in which a metal or non-metal atom is inserted into a silicon nitride lattice. Further, the upper pad layer 19 may be formed of silicon nitride (SiN) or silicon oxide nitride (SiON). A photoresist layer is formed on the upper pad layer 19. The photoresist layer may be formed using a well-known semiconductor photo process. The photoresist layer may be formed to overlap the active region 9 and to have an opening exposing the upper pad layer 19. The upper pad layer 19, and the intermediate pad layer 16 may be sequentially etched, and the lower pad layer 13 may be partially etched using the photoresist layer as an etch mask to thereby form a channel-induced hole 21 as illustrated in FIG. 1 or 4. As a result, the channel-induced hole 21 may be formed to expose the lower pad layer 16. After the channel-induced hole 21 is formed in the lower pad layer 13, the intermediate pad layer 16, and the upper pad layer 19, the photoresist layer is removed from the semiconductor substrate 3. Subsequently, a channel spacer layer 23 is formed on the upper pad layer 19 to conformally cover the channel-induced hole 21 as illustrated in FIG. 4. The channel spacer layer 23 may be formed of an insulating material having the same etch rate as the upper pad layer 19. A channel impurity diffusion region 35 is formed below the upper surface of the active region 9 by implanting impurity ions into the active region 9 through the channel-induced hole 21 using the channel spacer layer 23 as a mask as illustrated in FIG. 4. The channel impurity diffusion region 35 may be diffused in the active region to have the same area as the bottom of the channel-induced hole 21. The channel impurity diffusion region 35 may be diffused in the active region 9 to be larger than the bottom of the channel-induced hole 21.

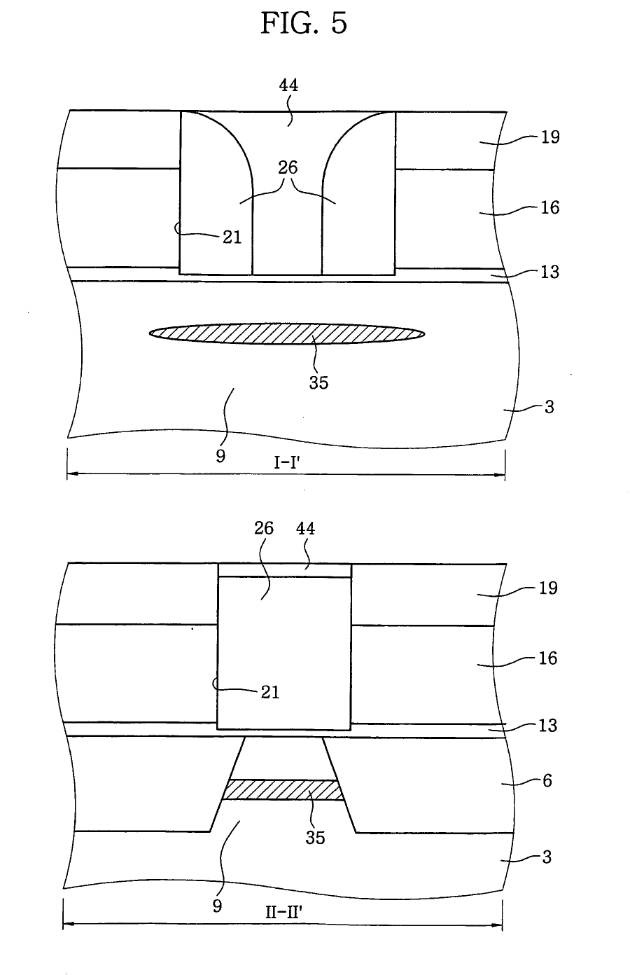

Referring to FIGS. 1 and 5, the channel impurity diffusion region 35 may have the same conductivity type as the semiconductor substrate 3. The channel impurity diffusion region 35 may have a different conductivity type from the semiconductor substrate 3. A channel spacer 26 surrounding a sidewall of the channel-induced hole 21 is formed by etching the entire surface of the channel spacer layer 23 to expose the upper pad layer 19 and the lower pad layer 13 as illustrated in FIG. 5. A channel plug 44 being in contact with the channel spacer 26 and the lower pad layer 13 and filling the channel-induced hole 21 is formed as illustrated in FIG. 5. The channel plug 44 may be formed of an insulating material having the same etch rate as the intermediate pad layer 16. The channel plug 44 may be formed to expose the upper pad layer 19. The channel plug 44 may be formed to expose the upper pad layer 19 and the channel spacer 26.

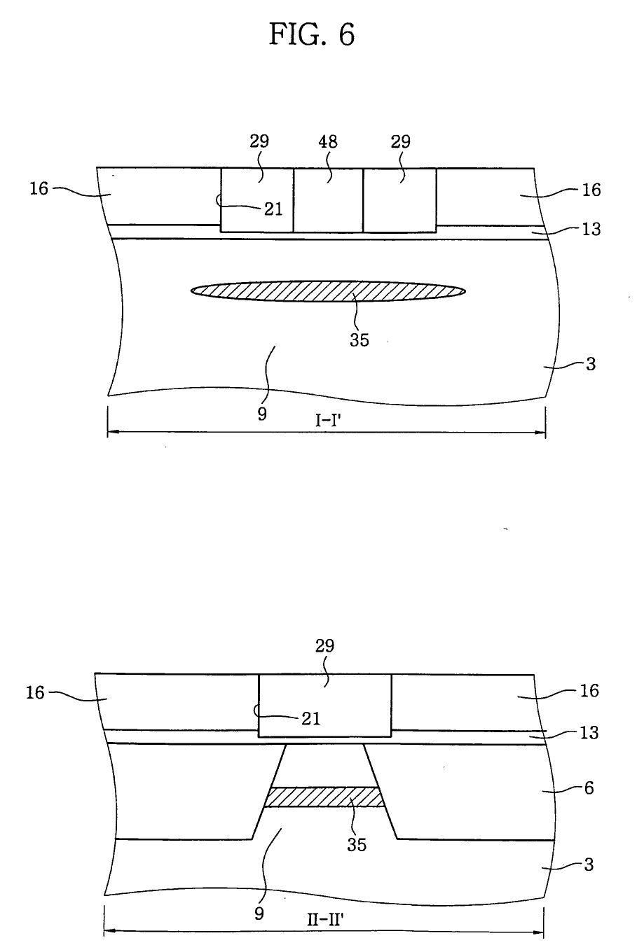

Referring to FIGS. 1 and 6, a planarization process is performed on the channel plug 44, the channel spacer 26, and the upper pad layer 19, so that the intermediate pad layer 16 is exposed. The planarization process may be performed using a chemical mechanical polishing or etch-back technique. The planarization process may be performed using an etchant having the same etch rate with respect to the intermediate pad layer 16, the upper pad layer 19, the channel spacer 26, and the channel plug 44. As a result, the planarization process may be performed to form a channel spacer pattern 29, and a channel plug pattern 48 in the channel-induced hole 21 as illustrated in FIG. 6. The channel spacer pattern 29 may be formed to be in contact with a sidewall of the channel-induced hole 21. The channel plug pattern 48 may be in contact with the channel spacer pattern 29, and fill the channel-induced hole 21.

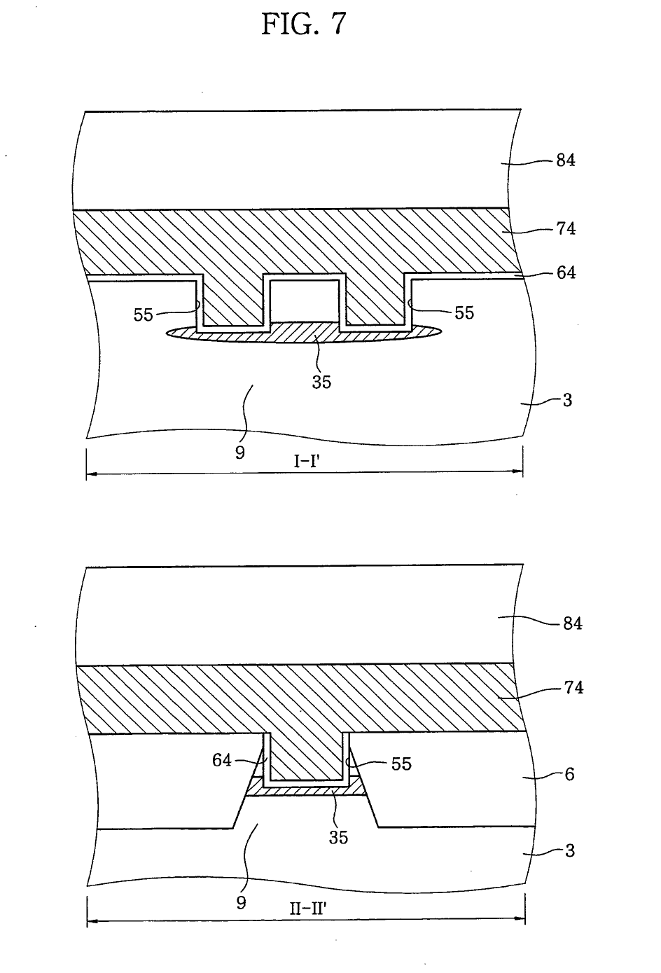

Referring to FIGS. 1 and 7, the channel spacer pattern 29 is removed from the semiconductor substrate 3 using the intermediate pad layer 16 and the channel plug pattern 48 as an etch mask, and the lower pad layer 13 as an etch buffer layer. Subsequently, gate trenches 55 are formed in the active region 9 by removing the lower pad layer 13 and partially etching the active region 9 using the intermediate pad layer 16 and the channel plug pattern 48 as an etch mask as illustrated in FIG. 7. Accordingly, the gate trenches 55 may be formed to extend downward from the upper surface of the active region 9. As a result, the gate trenches 55 may be formed to expose the channel impurity diffusion region 35. Unlike conventional art, the gate trenches 55 may continuously maintain a good alignment relationship with the channel impurity diffusion region 35 through the channel-induced hole 21. After the gate trenches 55 are formed within the active region 9, the lower pad layer 13, the intermediate pad layer 16, and the channel plug pattern 48 are removed from the semiconductor substrate 3.

A gate insulating layer 64 is formed on the active region 9 as illustrated in FIG. 7. The gate insulating layer 64 may be formed of the same material as the intermediate pad layer 16. The gate insulating layer 64 may be formed of silicon oxide or metal oxide. A gate layer 74 and a gate capping layer 84 are sequentially formed on the gate insulating layer 64 and the isolation layer 6 to fill the gate trench 55 as illustrated in FIG. 7. The gate layer 74 may be formed of a silicon-based conductive material and a metal silicide-based conductive material that are sequentially stacked. The gate layer 74 may be formed of only a silicon-based conducive material. Also, the gate layer 74 may be formed of metal nitride. As a result, the gate layer 74 may be in contact with the gate insulating layer 64 in the active region 9, and be in contact with the isolation layer 6 on the isolation layer 6. The gate capping layer 84 may be formed of an insulating material having the same etch rate as the channel spacer layer 23.

Referring to FIGS. 1 and 8, photoresist patterns are formed on the gate capping layer 84. The photoresist patterns may be formed using a well-known semiconductor photo process. The photoresist patterns may be formed to overlap each of the gate trenches 55. Gate patterns 94 may be formed by sequentially etching the gate capping layer 84 and the gate layer 74 using the photoresist patterns as an etch mask as illustrated in FIG. 1 or 8. Each of the gate patterns 94 may be formed to have a gate 78 and a gate capping pattern 88 that are sequentially stacked. The photoresist patterns are removed from the semiconductor substrate 3. At this time, the gate patterns 94 may protrude from the upper surface of the active region 9, extend downward from the upper surface of the active region 9, and extend toward the isolation layer 6 from the upper surface of the active region 9 in parallel with the upper surface of the active region 9. The channel impurity diffusion region 35 may be formed to have different volumes at both sides of the respective gate patterns 94. Accordingly, the gate patterns 94 may constitute a transistor 100 according to the present invention together with the channel impurity diffusion region 35.

As described above, the present invention provides transistors having a gate pattern suitable for self-alignment with a channel impurity diffusion region in an active region, and methods of forming the same. According to the present invention, the transistors may have gate patterns and a channel impurity diffusion region that are continuously well aligned with each other, which is not easily affected by a semiconductor photo process.

Exemplary embodiments of the present invention have been described herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A transistor comprising:
an isolation layer disposed in a semiconductor substrate to define an active region;
a first gate pattern protruding from an upper surface of the active region, and extending downward from the upper surface of the active region, the first gate pattern extending from the active region to be parallel to the upper surface of the active region and being in contact with an upper surface of the isolation layer; and
a channel impurity diffusion region disposed below the upper surface of the active region, surrounding the first gate pattern, and having different volumes at both sides of the first gate pattern.

2. The transistor of claim 1, further comprising a second gate pattern spaced apart from the first gate pattern by a predetermined distance, disposed in the active region, and surrounded by the channel impurity diffusion region,
wherein the second gate pattern protrudes from the upper surface of the active region, extends downward from the upper surface of the active region, and extends from the active region in parallel with the upper surface of the active region to thereby be in contact with the upper surface of the isolation layer.

3. The transistor of claim 2, wherein the first and second gate patterns are respectively disposed at both edges of the channel impurity diffusion region along the active region to sequentially pass through the patterns.

4. The transistor of claim 3, wherein the channel impurity diffusion region has different volumes at both sides of the second gate pattern.

5. The transistor of claim 4, wherein the channel impurity diffusion region is formed to be smaller than the upper surface of the active region and to face the upper surface of the active region.

6. The transistor of claim 5, further comprising a gate insulating layer disposed on the active region to pass through between the first gate pattern, the second gate pattern, and the active region,
wherein the gate insulating layer is in contact with the channel impurity diffusion region below the first and second gate patterns.

7. The transistor of claim 6, wherein each of the first and second gate patterns has a gate and a gate capping pattern that are sequentially stacked, and the gate insulating layer electrically insulates the first gate pattern, the second gate pattern, and the active region from one another, and partially surrounds the gate.

8. The transistor of claim 7, wherein the gate insulating layer is formed of at least one of silicon oxide and metal oxide.

9. The transistor of claim 8, wherein the gate insulating layer is formed of a material in which a metal or non-metal atom is inserted into a silicon oxide lattice.
